(19) United States
(12) Patent Application Publication
(10) Pub. No.: US 2014/0240922 A1
(43) Pub. Date: Aug. 28, 2014

(54) ELECTRONIC DEVICE AND REAR CASE OF ELECTRONIC DEVICE

(71) Applicant: Fujitsu Mobile Communications Limited, Kawasaki-shi (JP)

(72) Inventors: YASUAKI WATANABE, Yokohama (JP); Toru Koike, Hachioji (JP); Hirokazu Todoroki, Kunitachi (JP); SATORU NOMA, Hino (JP)

(73) Assignee: Fujitsu Mobile Communications Limited, Kawasaki-shi (JP)

(21) Appl. No.: 14/175,384

(22) Filed: Feb. 7, 2014

(30) Foreign Application Priority Data
Feb. 27, 2013 (JP) 2013-037561

(51) Int. Cl. H05K 7/20; G06F 1/20

(52) U.S. Cl. CPC H05K 7/20409; G06F 1/203
USPC 361/679.54; 361/707

(57) ABSTRACT

An electronic device having a heat generating part in an internal space between a front case and a rear case wherein the rear case is integrally molded with a metal sheet and the metal sheet is given relief shapes which increase its surface area, whereby the heat of the heating generating part is dissipated from the rear case and conduction to the front case is reduced. The relief shapes can be formed from a wave shape. The rear case may be made a bathtub shape. Relief shapes of the metal sheet may be exposed at the inside space of the electronic device at the side wall part of the rear case or its vicinity. As a result, the heat which is generated inside the housing of a small electronic device can be efficiently dissipated from the back side and conduction of heat to the front side can be made difficult.

### CROSS-REFERENCE TO RELATED APPLICATION

This application claims priority from, and incorporates by reference the entire disclosure of, Japanese Patent Application No. 2013-037561, filed on Feb. 27, 2013.

### FIELD

The present application relates to an electronic device which contains a heat generating part wherein the heat which is generated by the heat generating part can be passed through a housing to be dissipated and relates to a rear case of such an electronic device.

### BACKGROUND

In recent years, camera, mobile phones, and other small electronic devices have been spreading in use. As the performance of the ICs (integrated circuits) which are built into these electronic devices is improved, it has become necessary to enable the heat which the ICs generate to escape to the outside of the housing of the electronic device.

As the heat dissipating structure of an electronic device, Japanese Laid-Open Patent Publication No. 2010-191270 discloses to provide a heat dissipating member which is comprised of a metal or other heat conducting material at a back side of a camera with a built-in projector and to dissipate the heat from the heat generating part through the heat dissipating part to the outside of the camera. Further, Japanese Laid-Open Patent Publication No. 2001-237577 discloses to provide a through hole in a housing at a lower side of the board which mounts the electronic components, attach inside of this through hole a heat dissipating part which is made by a metal material, and dissipate the heat which is generated from the electronic component to the outside of the housing. Furthermore, Japanese Laid-Open Patent Publication No. 2004-281977 discloses to provide a plurality of through holes at the part of the housing of the electronic device where heat dissipation is required, spray molten metal particles from outside of the through holes to build up at the through holes and outer surface and form a heat dissipating part, and dissipate heat which was generated at the inside to the outside.

On the other hand, in an electronic device such as a mobile phone (including smart phones), when there is a waterproofing structure between the front case and rear case, the battery is arranged at the rear case and is covered by a battery cover. FIG. 1A is a view of a smart phone 10 of the related art as seen from the front side. The housing 11 is provided with a front case 1 at which a display 13 is provided, a rear case 2, and a battery cover 3 which is detachably attached to the rear case 2. FIG. 1B is a view of the smart phone 10 which is illustrated in FIG. 1A as seen from the back side. The shape of the battery cover 3 which is attached to the rear case 2 can be understood from this figure.

In this regard, the smart phone 10 of the structure which is explained from FIG. 1A to FIG. 1C is a structure where, due to the following factors, the heat which is generated at the electronic component 8 is easily conducted to the liquid crystal panel 4 at the front case 1.
Factor 1: The heat source is at front case 1 side.
Factor 2: A metal sheet 5, which easily conducts heat, is integrally formed with the front case 1. This is because the rear case 2 which forms the back side is mostly formed by an opening part due to the battery 9 being housed and therefore is weak in strength, so the strength of the overall set of the smart phone 10 is made up for by the front case 1.
Factor 3: There is a battery cover 3, so there is an air layer between the heat which is trapped inside the set and the outside to which the heat is desired to be dissipated and therefore conduction of the heat to the back side is difficult.

FIG. 1C is a cross-sectional view in the short direction of the smart phone 10 which is illustrated in FIG. 1A and FIG. 1B. It explains the internal structure of a smart phone 10 of the related art. The shapes of the members do not match the shapes of the members which are illustrated in FIG. 1A and FIG. 1B. At the top surface of the front case 1 of the smart phone 10, a liquid crystal panel 4 is attached. Below the liquid crystal panel 4, there is a liquid crystal module 6 which is supported by a metal sheet 5 which is formed integrally with the front case 1. The front case 1 is made of plastic, while the metal sheet is made of metal. Further, in the rear case 2, there is a circuit board 7. On the top surface of the circuit board 7, an electronic component 8 is mounted. The electronic component 8 is an integrated circuit or other mounted part and acts as a heat source. Further, inside of the rear case 2, a battery 9 is housed. The battery cover 3 is attached to the rear case 2.

Note that, in the smart phone 10 which is illustrated as related art, waterproofing packing is attached between the front case 1 and the rear case 2 etc. so as to prevent water from entering the inside, but illustration is omitted in FIG. 1B.

In this way, in the smart phone 10 of the related art, the heat at the inside of the housing 11 is easily conducted to the front side. The front side directly contacts the human body, so there was the issue of a large risk of low temperature burns etc. Further, in the case of a smart phone 10 which has a waterproofing structure, the housing 11 is high in air-tightness, and heat easily is trapped inside of the housing 11. For this reason, in a smart phone, it is desirable that the heat which is generated at the inside be hard to contact the human body and be efficiently dissipated to the outside.

### SUMMARY

In one aspect, the present application has as its object the provision of a small electronic device such as a smart phone which can efficiently dissipate heat which is generated inside a housing from a back side and make conduction of heat to the front side difficult. In another aspect, the present application has as its object the provision of a rear case of a small electronic device such as a smart phone which can efficiently dissipate heat which is generated inside a housing from a back side and make conduction of heat to the front side difficult.

According to one aspect of the embodiment, there is provided an electronic device which is provided with a front case and a rear case and which is provided with a heat generating part in an internal space which is surrounded by the front case and the rear case, in which electronic device, a metal sheet is integrally molded with the rear case and the metal sheet is given relief shapes which increase the length from one end to another.

According to another aspect of the embodiment, there is provided a rear case of an electronic device which is provided with a heat generating part in an inside space which is surrounded by a front case and rear case, in which rear case of an electronic device, a metal sheet is integrally molded with the rear case and the metal sheet is given relief shapes which increase the length from one end to another.

### BRIEF DESCRIPTION OF DRAWINGS

FIG. 1A is a perspective view of a smart phone of one example of a mobile terminal device as seen from a front side.

FIG. 1B is a perspective view of the smart phone which is illustrated in FIG. 1A as seen from a rear side.

FIG. 1C is a cross-sectional view along a short direction of the smart phone which is illustrated in FIG. 1A and FIG. 1B.

FIG. 2A is a cross-sectional view which illustrates a structure of an electronic device of a first embodiment of the present application.

FIG. 2B is a see-through view which illustrates a structure of a rear case unit of the electronic device which is illustrated in FIG. 2A.

FIG. 3A is a cross-sectional view which illustrates the structure of an electronic device of a second embodiment of the present application.

FIG. 3B is a perspective view which illustrates a structure of metal sheet which is contained in a rear case of the electronic device which is illustrated in FIG. 3A.

FIG. 4A is a back view of an electronic device as seen from its back side.

FIG. 4B is a plan view of a metal sheet which is contained in the rear case which is illustrated in FIG. 4A.

FIG. 4C is a cross-sectional view along a line C-C of the metal sheet which is illustrated in FIG. 4B.

FIG. 4D is a partial cross-sectional view of a part A of the electronic device which is illustrated in FIG. 4B.

FIG. 5A is a partial enlarged cross-sectional view which illustrates part of the process for producing a rear case of an electronic device of a third embodiment of the present application.

FIG. 5B is a cross-sectional view which illustrates a rear case of an electronic device of the third embodiment which is produced by the method of production of FIG. 5A.

FIG. 6A is a cross-sectional view of a rear case which is used in an electronic device of a fourth embodiment of the present application.

FIG. 6B is a cross-sectional view of a rear case which is used in an electronic device of a fifth embodiment of the present application.

FIG. 6C is a cross-sectional view of a rear case which is used in an electronic device of a sixth embodiment of the present application.

FIG. 6D is a cross-sectional view of embossed metal sheet which is contained in a rear case which is used in an electronic device of a seventh embodiment of the present application.

### DESCRIPTION OF EMBODIMENTS

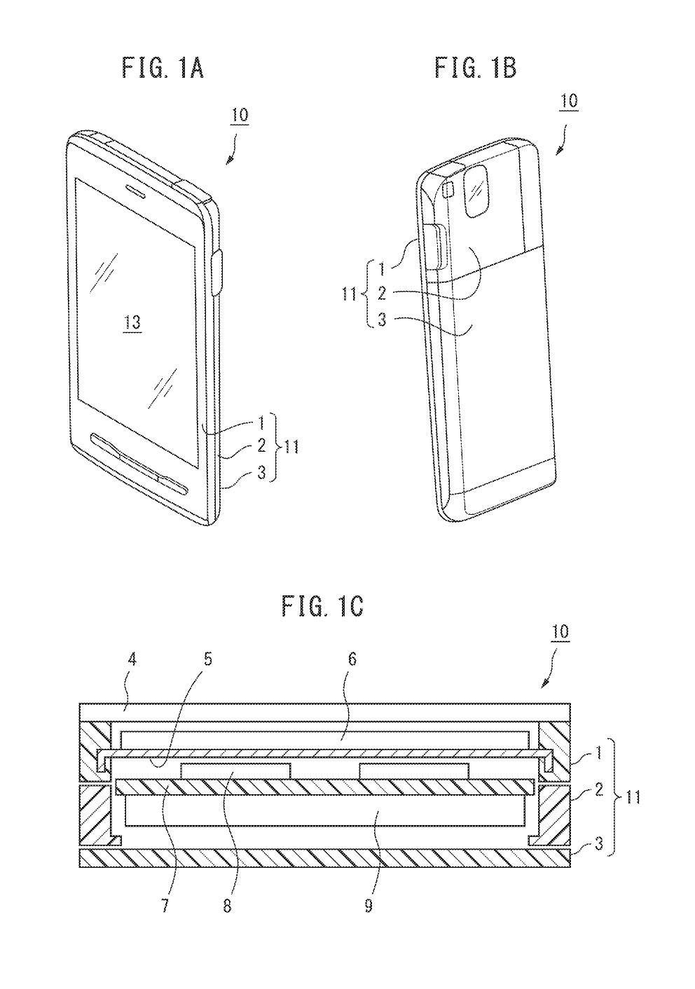

Below, the attached drawings will be used to explain in detail the embodiments of the present application based on specific examples. Note that, component members which are the same as the component members which are used for the smart phone of the related art which was illustrated in FIG. 1C are assigned the same notations for the explanation.

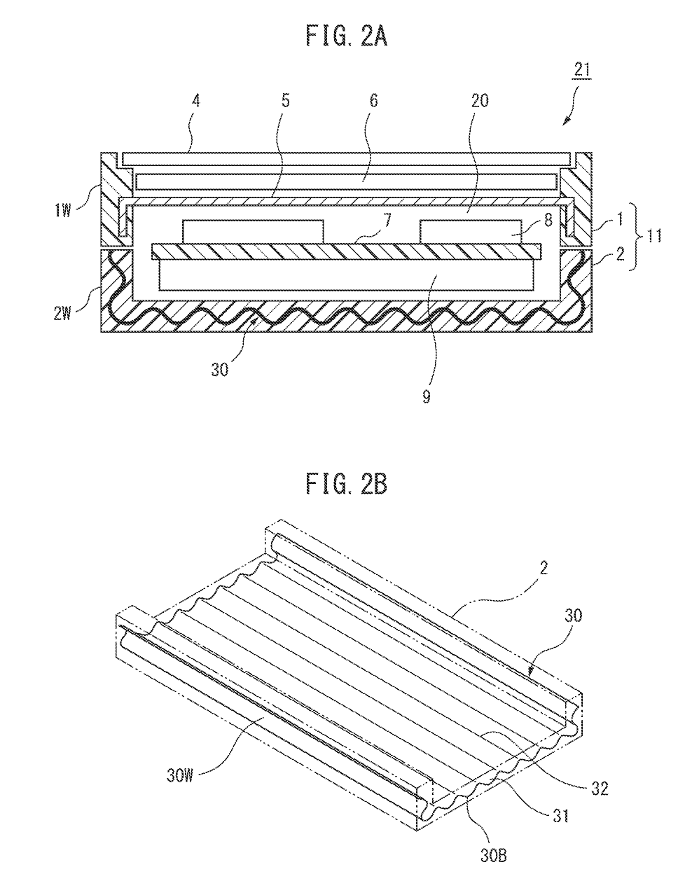

FIG. 2A is a cross-sectional view which illustrates the structure of a smart phone 21 of an electronic device of a first embodiment of the present application. At the top surface of a front case 1 of the smart phone 21, a liquid crystal panel 4 is attached. Below the liquid crystal panel 4, there is a liquid crystal module 6 which is supported by a metal sheet 5 which is integrally molded with a side wall part 1W of the front case 1. The front case 1 is made of plastic, while the metal sheet is made of metal. Further, a rear case 2 of the smart phone 21 is plate shaped and is provided with a side wall part 2W with an edge raised to the front case 1 side. This side wall part 2W is joined with the side wall part 1W of the front case 1. The joined part of the side wall part 1W and the side wall part 2W is provided with a waterproofing packing etc., but this is not illustrated in this figure. At the inside space 20 of the rear case 2 and the metal sheet 5, there is a circuit board 7. On the top surface of the circuit board 7, an electronic component 8 is mounted. The electronic component 8 is an integrated circuit or other mounted part and is a heat generating element. Further, at the bottom surface of the circuit board 7, a battery 9 is attached.

In the present application, a metal sheet 30 is embedded in the plate-shaped rear case 2. FIG. 2B is a see-through view which illustrates a structure of a rear case 2 unit of the smart phone 21 which is illustrated in FIG. 2A and illustrates an embodiment of the shape of the metal sheet 30 which is contained in the rear case 2. When embedding the metal sheet 30 in the rear case 2, if using a known injection molding machine, the metal sheet 30 is embedded in the rear case 2 by integral molding. The metal sheet 30 which is embedded in the rear case 2 is provided with a bottom part 30B and a wall part 30W matched with the shape of the rear case 2.

Further, the shape of the metal sheet 30 which is embedded in the rear case 2 is not a flat plate shape, but is a shape which is given relief shapes which increase the surface area of the metal sheet 30. The shape of the metal sheet 30 of the smart phone 21 of the first embodiment is a cross-sectional wave shape formed in the horizontal direction (short direction) of the smart phone 21 and has recessed parts 31 and projecting parts 32. The recessed parts 31 and projecting parts 32 are provided with periodicity and appear alternately in the horizontal direction (short direction) of the smart phone 21. The wave shape of the metal sheet 30 may also be formed in the vertical direction (long direction) of the smart phone 21.

In the smart phone 21 of the first embodiment, the heat which is generated by the heat source constituted by the electronic component 8 is conducted to the metal sheet 30 which is embedded in the rear case 2 and is dissipated from the bottom part 30B to the wall part 30W, so the heat can be easily released to outside of the rear case 2. That is, it is possible to reduce the influence of the above-mentioned factor 2 to the front side of the smart phone 21. Further, by making the metal sheet 30 a wave shape so as to increase the surface area, it becomes possible to raise the heat dissipation effect.

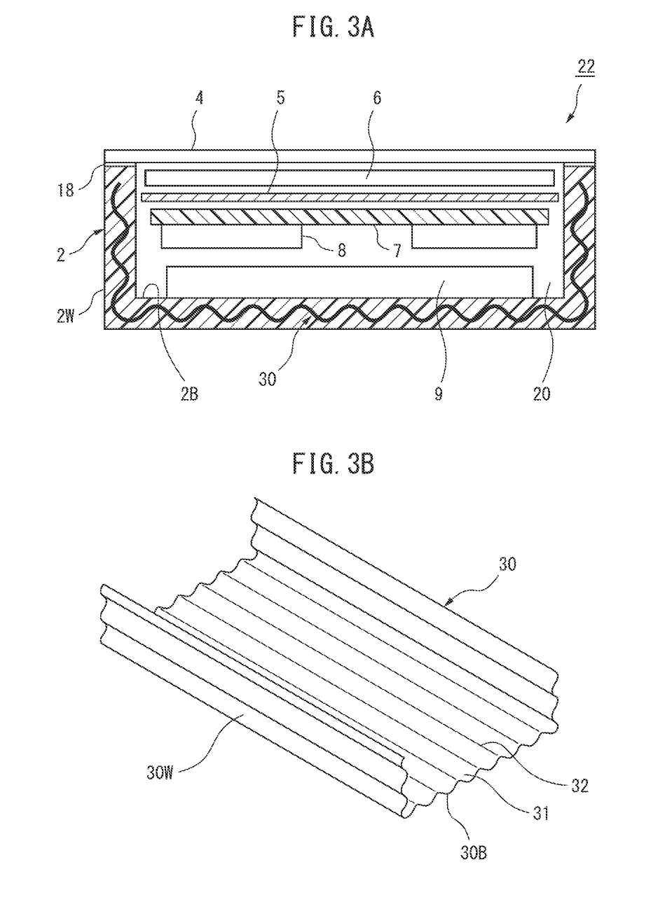

FIG. 3A is a cross-sectional view which illustrates the structure of an electronic device of a second embodiment of the present application constituted by a smart phone 22. The smart phone 22 of the second embodiment is provided with a rear case 2 of a bathtub structure. No front case is provided. The side wall part 2W of the rear case 2 of the bathtub structure is high in height. The liquid crystal panel 4 is directly attached by a binder 18 to the side wall part 2W of the rear case of the bathtub structure. Instead of the binder 18, two-sided tape may also be used.

At an inside space 20 which is surrounded by the liquid crystal panel 4 and the bottom part 2B of the rear case 2, a liquid crystal module 6 which is supported by a metal sheet 5 and a circuit board 7 on which an electronic component 8 is mounted are provided. Further, at the bottom part 2B of the rear case 2, a battery 9 is attached. The positions of the circuit board 7 on which the electronic component 8 is mounted and the battery 9 which are arranged in the inside space 20 which is surrounded by the liquid crystal panel 4 and the bottom part 2B of the rear case 2 are not limited to these positions. The positions may be reversed.

In the smart phone 22 of the second embodiment, a metal sheet 30 is embedded at the bottom part 2B and side wall part 2B of the bathtub structure rear case 2. FIG. 3B illustrates one embodiment of the shape of the metal sheet 30 which is embedded in the rear case 2 which is illustrated in FIG. 3A. When embedding the metal sheet 30 in the rear case 2, if using a known injection molding machine, the metal sheet 30 is embedded in the rear case 2 by integral molding. The metal sheet 30 which is embedded in the rear case 2 is provided with a bottom part 30B and wall part 30W matching the rear case 2 of the bathtub structure.

The shape of the metal sheet 30 is not a flat plate shape, but is a shape which is given relief shapes which increase the surface area of the metal sheet 30. The shape of the metal sheet 30 of the smart phone 22 of the second embodiment is a cross-sectional wave shape formed in the horizontal direction (short direction) of the smart phone 22 and has recessed parts 31 and projecting parts 32. The recessed parts 31 and projecting parts 32 are provided with periodicity and appear alternately in the horizontal direction (short direction) of the smart phone 22. The wave shape of the metal sheet 30 may also be formed in the vertical direction (long direction) of the smart phone 22 or in a combined shape at both, at a slant, etc. Further, the wall part 30W may also be arranged at all of the four sides of the bottom part 30B.

In a smart phone 2 which uses a bathtub structure rear case 2, the battery and other parts which have to be taken out or the external terminals etc., while not illustrated, should be structured to be taken out at the side face of the rear case 2. In the smart phone 22 of the second embodiment, the heat which is generated by the heat source constituted by the electronic component 8 is conducted to the metal sheet 30 which is embedded in the rear case 2 where it is dissipated from the bottom part 30B to the wall part 30W, so the heat is easily dissipated to the outside of the rear case 2. That is, it is possible to reduce the influence of the above-mentioned factor 2 of heat being easily conducted to the front side of the smart phone 22. Further, by making the metal sheet 30 a wave shape and extending it to the side wall part 2W of the rear case 2 to increase the surface area, it becomes possible to greatly enhance the heat dissipation effect.

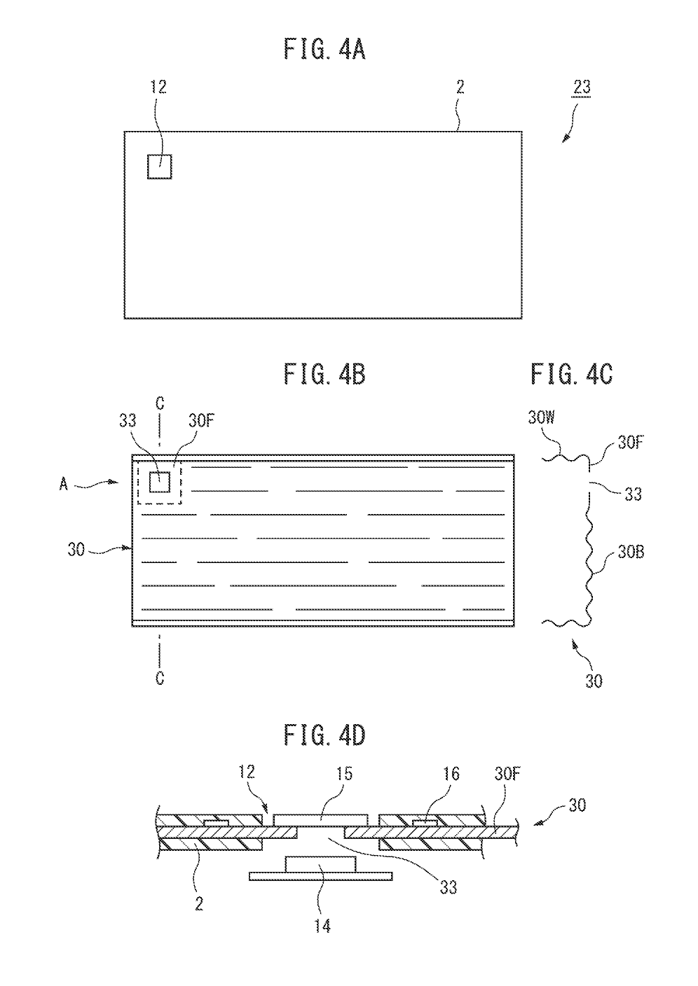

FIG. 4A is a view of a smart phone 23 as seen from the back side. This smart phone 23 is provided with an opening part 12 at the side surface for emitting sound from the speaker. When, in this way, the back surface of the smart phone 23 is provided with the opening part 12, as illustrated in FIG. 4B, the portion of the metal sheet 30 which is embedded in the rear case 2 which corresponds to the position of the opening part 12 is formed at the flat part 30F. Further, the part where the flat part 30F overlaps the opening part 12 is provided with a through hole 33. FIG. 4C illustrates the cross-sectional shape of the metal sheet 30 along the line C-C of FIG. 4B. The part of the metal sheet 30 other than the flat part 30F is provided with relief shapes of a wave shape in the same way as the first embodiment.

Furthermore, FIG. 4D is a cross-sectional view which illustrates partially enlarged a part A of the smart phone 23 which is illustrated in FIG. 4B. When the rear case 2 is a bathtub structure, the back side of the rear case 2 is provided with an opening part 12 of a speaker etc., but the opening part 12 may be dealt with by providing a flat part 30F at the integral molded metal sheet 30 and exposing part of the metal sheet 30. That is, when the back surface of the smart phone 23 is provided with the opening part 12, the part of the metal sheet 30 which is embedded in the rear case 2 which corresponds to the opening part 12 is formed at the flat part 30F and this flat part 30F is provided with a through hole 33. The through hole 33 can be provided by utilizing the positioning hole which is formed at the time of molding the rear case 2. In this embodiment, at the inside of the rear case 2 which corresponds to the opening part 12, a speaker 14 is provided. The sound from the speaker 14 is emitted to the outside through the through hole 33 of the metal sheet 30.

Further, when the smart phone 23 is a waterproof specification, the flat part 30F of the metal sheet 30 around the through hole 33 is provided with a waterproof mesh 15 which passes sound, but does not pass moisture. Further, the rear case 2 around the opening part 12 is provided with heat activated waterproof tape with the flat part 30F of the metal sheet 30. Moisture is prevented from entering inside the rear case 2 by this. Note that, by using a metal sheet which is coated on its surface with a plastic, the heat activated waterproof tape 16 can also be omitted.

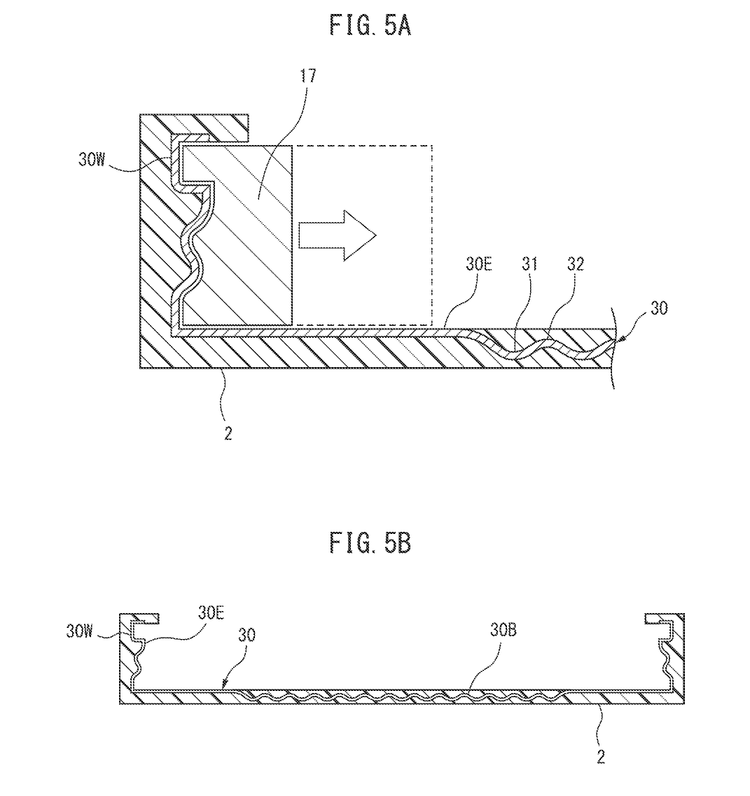

Further, when the rear case 2 is a bathtub structure, since the side wall part 2W of the rear case 2 is high in height, there is a possibility of the metal sheet becoming loose at the time of molding the rear case 2. In such a case, it is sufficient to place a holding structure in the mold. This will be explained while using FIG. 5A and FIG. 5B.

FIG. 5A is a partial enlarged cross-sectional view which illustrates part of the process for producing the rear case 2 of the electronic device of the third embodiment of the present application. Illustration of the mold for forming the rear case 2 as a whole will be omitted, but when preventing the metal sheet from becoming loose at the time of molding the rear case 2, the mold may be provided with a slide mold 17. The slide mold 17 is generally attached to the male half of the mold. In insert molding, the slide mold 17 holds down the wall part 30W of the metal sheet until the plastic is injected between the female half and male half. Further, after the injection molding is finished, the slide mold 17 moves in the direction which is illustrated by the arrow, so the rear case 2 in which the metal sheet 30 is embedded can be detached from the male die.

Note that, the slide mold 17 slides in the direction which is illustrated by the arrow after injection molding, so the part of the metal sheet 30 where the slide mold 17 moves requires an exposed part 30E which is exposed at the inside of the rear case 2. The part of the metal sheet 30 other than where the slide mold 17 moves, as illustrated in FIG. 5A, is embedded inside of the rear case 2 in the same way as the above-mentioned embodiment and is embedded in the state provided with the recesses 31 and projections 32. FIG. 5B is a cross-sectional view which illustrates a rear case 2 which is used in the smart phone of the third embodiment which is produced by the method of production which is illustrated in FIG. 5A. If, in this way, there is an exposed part 30E of the metal sheet 30 at the inside surface of the rear case 2, conduction of the heat which is generated inside of the smart phone to the metal sheet 30 becomes easy and the conduction of heat to the front side is suppressed more.

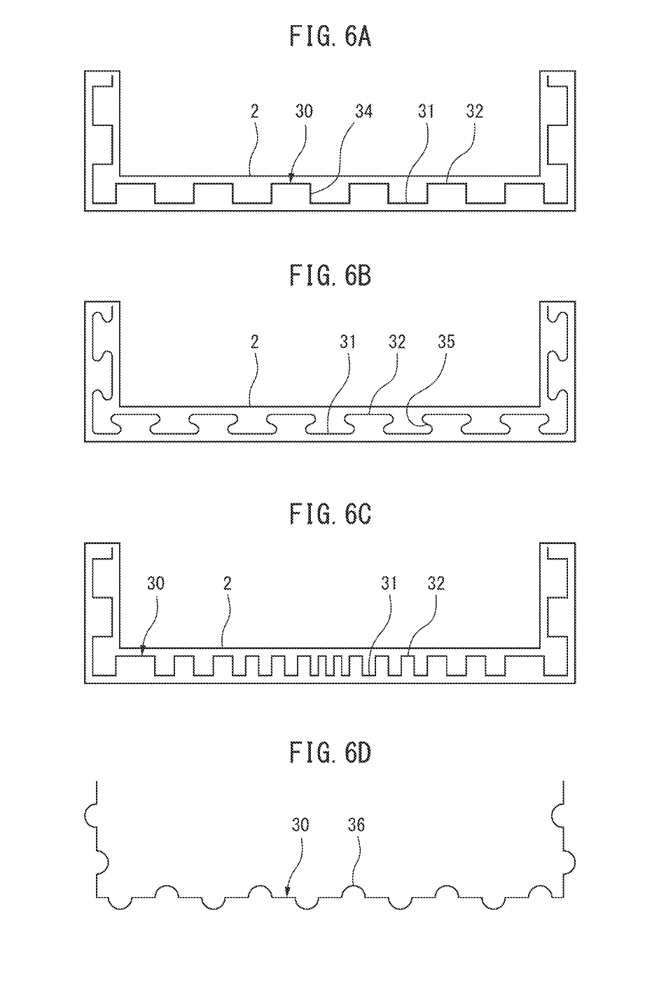

Above, several examples of the structure of the rear case of the present application which was used for a smart phone were explained, but the shape of the relief shapes of the metal sheet which is embedded in the rear case is not limited to the above embodiment. Other shapes of the relief shapes of the metal sheet will be further explained using FIG. 6A to FIG. 6D.

FIG. 6A illustrates the cross-section of a rear case 2 which is used for a smart phone of a fourth embodiment of the present application. In the fourth embodiment, the relief shapes which are formed at the metal sheet 30 are formed by a cross-sectional pulse wave shape which has recessed parts 31 and projecting parts 32 in either direction of the horizontal direction and vertical direction of the smart phone. The recessed parts 31 and the projecting parts 32 are repeatedly formed by a certain period. Note that, the boundary parts 34 of the recessed parts 31 and projecting parts 32 of this embodiment rise up vertically with respect to the recessed parts 31 and projecting parts 32, but they may also be shapes which rise in a slanted direction. Further, the recessed parts 31 and projecting parts 32 may also be shapes combining ones in both the horizontal direction and vertical direction or including the slanted direction etc. in combination.

FIG. 6B illustrates the cross-section of a rear case 2 which is used for a smart phone of a fifth embodiment of the present application. In the fifth embodiment, the metal sheet 30 which is provided with the pulse wave shape cross-section which is illustrated in FIG. 6A is further provided with relief parts 35 at the boundary parts 34 of the recessed parts 31 and projecting parts 32. The relief parts 35 at the boundary parts 34 of the recessed parts 31 and projecting parts 32 can be formed by crushing the two sides of the projecting parts 32 by a fixture. In this way, by further providing relief parts 35 at the boundary part 34 of the recessed parts 31 and projecting parts 32, the plastic will become rooted in the metal sheet 30 and the adhesion of the plastic and metal sheet 30 will be raised. Due to this, it is possible to make the rear case 2 one which is provided with a high heat dissipating effect and a high strength.

FIG. 6C illustrates the cross-section of a rear case 2 which is used for a smart phone of a sixth embodiment of the present application. In the fourth embodiment, the cross-sectional pulse wave shape relief shapes which were formed at the metal sheet 30 were formed by the same period. On the other hand, in the sixth embodiment, the cross-sectional pulse wave relief shapes which are formed at the metal sheet 30 are denser at some parts and sparser at other parts. That is, in the sixth embodiment, the period of repetition of the cross-sectional pulse wave shape relief shapes is not constant. When making the period of repetition of the cross-sectional pulse wave shape relief shapes different in this way, it is considered that if making the period shorter the closer the location to the source of generation of heat in the smart phone, the heat dissipation effect would be large. The period of the relief shapes which are formed at the metal sheet 30 may be changed in the cross-sectional wave type relief shapes which were explained in the first to third embodiments.

FIG. 6D illustrates a cross-section of the rear case 2 which is used for a smart phone of a seventh embodiment of the present application. In the seventh embodiment, the metal sheet 30 is provided with a plurality of embossed parts 36 so as to provide the metal sheet 30 with relief shapes. The embossed parts 36 may be provided so as to stick out only at one surface of the metal sheet 30. Further, as illustrated in FIG. 6D, they may be provided to stick out at both surfaces of the metal sheet 30. Furthermore, the embossed parts 36 may be formed arranged in several lines on the metal sheet 30. Further, they may be randomly formed on the metal sheet 30.

As explained above, according to the electronic device and the rear case of the electronic device of the present application, there are the following effects:
(1) Due to dissipation of heat which is generated inside of the housing to the back side of the rear case, conduction of heat to the front side is prevented.
(2) Due to metal sheet being embedded in the rear case, the strength of the rear case is improved.
(3) Due to elimination of the battery cover etc., the number of parts is slashed and the cost is cut.
(4) Due to no waterproof packing being used, the water stopping performance can be improved.
(5) The electronic device, in particular a smart phone, can be reduced in thickness and size, simplified in assembly, and decreased in number of work hours for assembly.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

What is claimed is:

1. An electronic device comprising:
a front case and a rear case;
a heat generating part provided in an internal space which is surrounded by the front case and the rear case; and
a metal sheet embedded in the rear case by integral molding which is given relief shapes for increasing the surface area thereof.

2. The electronic device according to claim 1, wherein said relief shapes are formed by a wave shape formed in either direction of a horizontal direction and vertical direction of said electronic device.

3. The electronic device according to claim 1, wherein said relief shapes are formed by a cross-sectional pulse wave shape which has recessed parts and projecting parts in either direction of a horizontal direction and vertical direction of said electronic device.

4. The electronic device according to claim 3, wherein boundary parts of recessed parts and projecting parts of said relief shapes of the pulse wave shape are further formed with relief shapes.

5. The electronic device according to claim 1, wherein said relief shapes are formed by embossing.

6. The electronic device according to claim 2, wherein the relief shapes of said wave shape and the relief shapes of the pulse wave shape are formed in either direction of a horizontal direction and vertical direction of said electronic device by a predetermined period.

7. The electronic device according to claim 6, wherein said predetermined period is shorter the closer the location to the source of generation of the heat in said electronic device.

8. The electronic device according to claim 1, wherein said rear case is a bathtub type.

9. The electronic device according to claim 8, wherein the relief shapes of the metal sheet are exposed at an inside space of said electronic device at the side wall part of the rear case and its vicinity.

10. The electronic device according to claim 1, wherein said electronic device is a waterproof specification and, when said rear case is provided with an opening part, said metal sheet corresponding to the opening part of said rear case is formed flat, a through hole corresponding to said opening part is formed, and said through hole is covered by a waterproofing member.

11. A rear case of an electronic device which is provided with a heat generating part in an inside space which is surrounded by a front case and rear case, in which rear case of an electronic device, a metal sheet is integrally molded with the rear case and the metal sheet is given relief shapes which increase the surface area.

12. The rear case according to claim 11, wherein said relief shapes are formed by a wave shape formed in either direction of a horizontal direction and vertical direction of said electronic device.

13. The rear case according to claim 11, wherein said relief shapes are formed by a cross-sectional pulse wave shape which has recessed parts and projecting parts in either direction of a horizontal direction and vertical direction of said electronic device.

14. The rear case according to claim 13, wherein rising parts and falling parts of recessed parts of the pulse wave shape are further formed with relief shapes.

15. The rear case according to claim 11, wherein said relief shapes are formed by embossing.

16. The rear case according to claim 11, wherein the relief shapes of said wave shape and the relief shapes of the pulse wave shape are formed in either direction of a horizontal direction and vertical direction of said electronic device by a predetermined period.

17. The rear case according to claim 16, wherein said predetermined period is shorter the closer the location to the source of generation of the heat in said electronic device.

18. The rear case according to claim 11, wherein said rear case is a bathtub type.

19. The rear case according to claim 18, wherein the relief shapes of the metal sheet are exposed at an inside space of said electronic device at the side wall part of the rear case and its vicinity.

20. The rear case according to claim 11, wherein said electronic device is a waterproof specification and, when said rear case is provided with an opening part, said metal sheet corresponding to the opening part of said rear case is formed flat, a through hole corresponding to said opening part is formed, and said through hole is covered by a waterproofing member.
